(19) United States
(12) Patent Application Publication
(10) Pub. No.: US 2007/0155350 A1
(43) Pub. Date: Jul. 5, 2007

(54) Method of frequency planning in an ultra wide band system

(75) Inventors: Behzad Razavi, Los Angeles, CA (US); Zaw Soe, Encinitas, CA (US)

Correspondence Address: THADDEUS GABARA, 62 BURLINGTON ROAD, MURRAY HILL, NJ, 07974, US

(73) Assignee: WIONICS RESEARCH, Irvine, CA (US)

(21) Appl. No.: 11/322,073

(22) Filed: Dec. 29, 2005

(51) Int. Cl. H03J 7/32

(52) U.S. Cl. 455/147; 455/146

(57) ABSTRACT

The present invention provides reduces the number of required synthesizers thereby reducing the area and power concerns to extract/insert a signal from/to a multi-channel communication system and is also known as frequency planning. The highest frequency of operation required for the synthesizers or oscillators is approximately the midpoint of the entire signal frequency range. Two superimposed Weaver architectures are used to form the architecture. The receiver extracts the baseband I and Q signals from the multi-channel communication system, while the transmitter upconverts the baseband I and Q signals to the multi-channel communication system. The Weaver architecture, depending on the select bit, can enhance the image signal and reduce the desired signal or the image signal can be reduced while the desired signal is enhanced. Because the image and signal components are symmetrically displaced from the RF LO, less IF LO frequencies or synthesizers are required to operate the system.

### CROSS-REFERENCE TO RELATED APPLICATIONS

The present application is related to the co-filed U.S. application entitled “APPARATUS AND METHOD FOR ULTRA WIDE BAND ARCHITECTURES” filed on Dec. 29, 2005, which are all invented by at least one common inventor as well as being assigned to the same entity as the present application and incorporated herein by reference in their entireties.

### BACKGROUND OF THE INVENTION

Ultrawideband (UWB) wireless technology is a high data rate (480+ Mbps), short range (up to 20 meters), and low power technology that promises to eliminate confusing cables and wires between interfaces. A de facto standard has emerged and is known as the MultiBand OFDM Alliance (MBOA). The FCC (Federal Communication Commission) has allocated an unlicensed radio spectrum from 3.2 GHz to 10.6 GHz for the MBOA-UWB technology.

The full bandwidth of 7.5 GHz is broken up into fourteen multiple carriers each having a 525 MHz bandwidth and in essence forming a multi-band system. The need to transfer data in one or more of these multiple carriers is determined in real time where various channels can be turned off or on under software control depending on the interference level of similar systems in the local environment.

Some typical applications include: video to/from computers and TV, residential gateways, PDA synchronization, and games to name a few. Various existing standards may utilize the UWB technology such as HDTV, SD, Media PC's, and video recorders.

The MBOA UWB specification has a total bandwidth of 3-10 GHz. As illustrated in FIG. 1a, the column BAND_ID of table 1-1 shows a total of 14 channels grouped into five band groups. The band groups 1 through 4 have three channels each while band group five has two channels. FIG. 1b illustrates the spectrum of the 14 channels of the UWB band where the center frequencies of each channel are identified. For example, spectrum 1-2 corresponds to the BAND_ID channel 7 located within the third Band Group of table 1-1.

The MBOA UWB specification requires very fast channel switching time in 3-10 GHz band. Devices operating in the first four groups require channel switching less than 9.47 nS.

An UWB specification is being formed in the 60 GHz range as well. FIG. 1c illustrates the bandwidth of this spectrum for three regions: Japan, Europe and the U.S. Note that oxygen can absorb some of the electromagnetic energy in this range.

The implementation of UWB RF transceiver imposes several design constrains in term of frequency planning. They are: the required switching time, the total number of synthesizers to cover wide frequency range and the frequency divider operating speed. Since it is very difficult to implement a synthesizer that can switch up to 1024 MHz in 9.47 nS the synthesizers need to be always enabled so that they generate a constant frequency without the need to alter the frequencies. This requires careful frequency planning to minimize the number of synthesizers and to allow for a feedback divider in the synthesizer at the lowest possible speed to enable a robust manufacturing yield. The hopping pattern Time Frequency Code in UWB specifies every band group needs to hop at least 3 channels while the 9.47 nS comes from the UWB specifications. The frequency plan can be improved by decreasing the need for requiring a single synthesizer for each channel. For instance, some frequencies can be obtained by dividing a higher synthesizer frequency by a multiple of two several times.

FIG. 2a illustrates a direct down conversion architecture 2-1. An antenna 2-2 and matching circuit (not shown) receives the external signal 2-3. A low noise amplifier 2-4 amplifies the received signal and applies it to the two mixers 2-5 and 2-6. A quadrature oscillator signal consisting of a I (in-phase) and a Q (quadrature) sinusoidal signals are applied to the two mixers 2-5 and 2-6 to downconvert the received signal into an IF_I and an IF_Q component, respectfully. These I and Q oscillator signals are also know as the local oscillators (LO). Low Pass Filters (LPF) 2-7 and 2-8 filter out the high frequencies components before applying the signal to the Programmable Gain Amplifier (PGA) 2-9 and 2-10. The output signals are the baseband I 2-11 and baseband Q 2-12.

FIG. 2b depicts the fixed local oscillators that can be selected by a multiplexer or MUX 2-14 to generate the I/Q signals 2-16 which can be applied, for example, to the mixers 2-5 and 2-6. These synthesizer or oscillator signals 2-15 or a subset of them can be sourced from an external lead, ring oscillators, LC tank circuits or Phase Lock Loops (PLL). The MUX 2-14 selects the I/Q signal that is applied to the down conversion architecture 2-1. Because these channel frequencies do not share a common denominator at a reasonable high frequency; up to 14 separate synthesizers may be required. Only one of the 14 LO's 2-15 is selected by the MUX 2-14 using the channel select signal 2-13.

Potential issues for the MUX 2-14 shown in FIG. 2b are as follows. The higher the channel frequency then there is a possibility for more quadrature mismatch, for instance, the I and Q signals may not be 90° out of phase with each other. In addition, carrier leakage may occur in the mixers degrading the recovered signal, and finally the receiver may suffer an output dc offset. Finally, in order to meet the 9.47 nS switching time that was mentioned earlier, the synthesizer requires that all 14 PLLs are in continuous operation which will cause high power dissipation levels.

The process technology and die yield is critical for low cost consumer product such as UWB devices. At 10 GHz, it may be difficult for the synthesizer feedback divider to fully function over PVT (Process, voltage, and Temperature) unless the design uses an advanced technology process which will increase the cost. Furthermore, forming 14 separate synthesizers may demand quite large die area increasing the overall cost of the die.

A variation of LO generation system 2-17 includes the use of one or more low speed synthesizers with several single side band (SSB) mixers to generate the required LO as shown in FIG. 2c. For example, the reference clock oscillator 2-18 is applied to the PLL 2-19 which generates a 6336 MHz signal on lead 2-20. The divide by 3 2-21 generates a 2112 MHz signal on lead 2-22. The divide by 2 2-23 generates a 1056 MHz signal on lead 2-24. Assume that the selector block 2-25 passes the signal on lead 2-24 to the SSB 2-26. If the selector block 2-27 passes the signal at the output of the SSB 2-26, the I/Q signal 2-28 will generate a signal frequency of 5280 MHz on its output lead where this signal needs to be in quadrature. The signal path from the 6336 MHz LO to the final output consist of I and Q signals, which require twice the number of dividers and selectors as shown in FIG. 2c. Note from FIG. 1a, in table 1-1, this corresponds to the Lower Frequency for BAND_ID channel 5.

For the circuit illustrated in FIG. 2c, the operating frequency of the divider is reduced. Each side band mixer will consume inductor area and power. Due to device mismatch, quadrature mismatch and limited linearity, this SSB mixer will produce spurs at the transmitter output. In addition, the receiver will be sensitive to interference at the spur locations. Moreover, the issues such as the quadrature mismatch, centered carrier leakage, receiver output dc offset still exists in this method.

FIG. 3 illustrates a low noise amplifier (LNA) 3-5 feeding a Weaver architecture 3-1. The external signal 3-2 arrives at the antenna 3-3. This antenna may exist off-chip or can be integrated on-chip. In particular, as the frequency of the RF signal increases (60 GHz), the physical size of the antenna decreases encouraging on-chip formation. A Band Pass Filter (BPF) 34 is used to filter some signal components before being applied to the LNA 3-5. A first adjustable LO 3-8 is used to downconvert the signal using the mixers 3-6 and 3-7 into I and Q components. A BPF 3-9 and 3-10 are used to filter the signal. A second constant LO 3-11 phase shifts one path by 90° with respect to the other and is again filtered by BPF's 3-14 and 3-15. The desired signal in each path to be enhanced by a factor of 2 while the summer 3-16 causes the image signal to be cancelled after passing through the summer 3-16. The final signal is available at lead 3-17. The Weaver architecture uses the energy in the desired signal between the two paths and combines them together while the image signal is configured to have an opposite polarity such that the combination eliminates the image components.

### BRIEF SUMMARY OF THE INVENTION

The present invention provides for a simpler technique to extract the signal from a multi-channel communication system. This technique reduces the number of required reference oscillators or synthesizers thereby reducing the area and power concerns of the architecture and is know as frequency planning. The highest frequency of operation required of the oscillators is approximately the mid point of the entire frequency range. For the MBOA standard, the frequency range is from 3.1 to 10.6 GHz and the mid point is 6864 GHz. Because the mid point frequency is reduced, some of the problems mentioned earlier such as the PVT concern and quadrature mismatch become less of a concern.

Two superimposed Weaver architectures are used to form the architecture. The receiver extracts the baseband I and Q signals from the multi-channel communication system, while the transmitter upconverts the baseband I and Q signals to the multi-channel communication system. The Weaver architecture, depending on the select bit, can enhance the image signal and reduce the desired signal or the image signal can be reduced while the desired signal is enhanced. An important aspect of this invention is that the image and the desired signal are located in channels symmetrically displaced from the RF LO. Thus, the image of the first LO is eliminated while the desired signal is enhanced after passing through this new architecture. Because of the image and signals components being symmetrically displaced from the RF LO, less IF LO frequencies are required to operate the system.

Thus, this new form of frequency planning for UWB offers advantages on several fronts including the reduction of area and power dissipation since the number of oscillators are decreased. In addition, the signal extraction is enhanced since a Weaver architecture is used. Our invention focuses on devices that operate over entire UWB band but can be applied for devices for limited band of operations. Another area where this invention can be used is in the newly formed 60 GHz UWB systems.

### BRIEF DESCRIPTION OF THE SEVERAL VIEWS OF THE DRAWINGS

FIG. 1a depicts a table indicating the 14 frequencies bands of the MBOA.

FIG. 1b illustrates the spectrum of a UWB system from 3 GHz to 10 GHz.

FIG. 1c illustrates the spectrum of a UWB system at 60 GHz.

FIG. 2a shows a direct conversion architecture generating baseband I and Q signals.

FIG. 2b depicts a MUX selecting one of all available LO frequencies.

FIG. 2c illustrates a simplified system that reduces the number of required LO frequencies.

FIG. 3 shows a Weaver architecture.

FIG. 4a shows a first architecture for frequency planning in accordance with the present invention.

FIG. 4b shows the frequency spectrum for frequency planning in accordance with the present invention.

FIG. 4c shows a second architecture for frequency planning in accordance with the present invention.

FIG. 4d shows a third architecture for frequency planning in accordance with the present invention.

FIG. 5 depicts fourth architecture for frequency planning in accordance with the present invention.

FIG. 6a depicts the signal spectrum, the LO, IF LO, and baseband signal in accordance with the present invention.

FIG. 6b lists the frequencies of the RF, LO and IF in accordance with the present invention.

FIG. 7a illustrates a prior art Weaver receiver architecture.

FIG. 7b illustrates receiver architecture for frequency planning in accordance with the present invention.

FIG. 7c illustrates an RSSI measurement technique in accordance with the present invention.

FIG. 8 illustrates the frequency planning at 60 GHz in accordance with the present invention.

FIG. 9 illustrates a receiver architecture at 60 GHz in accordance with the present invention.

FIG. 10 illustrates a transmitter architecture at the 3 GHz to 10 GHz range in accordance with the present invention.

FIG. 11 illustrates a transmitter architecture at the 60 GHz range in accordance with the present invention.

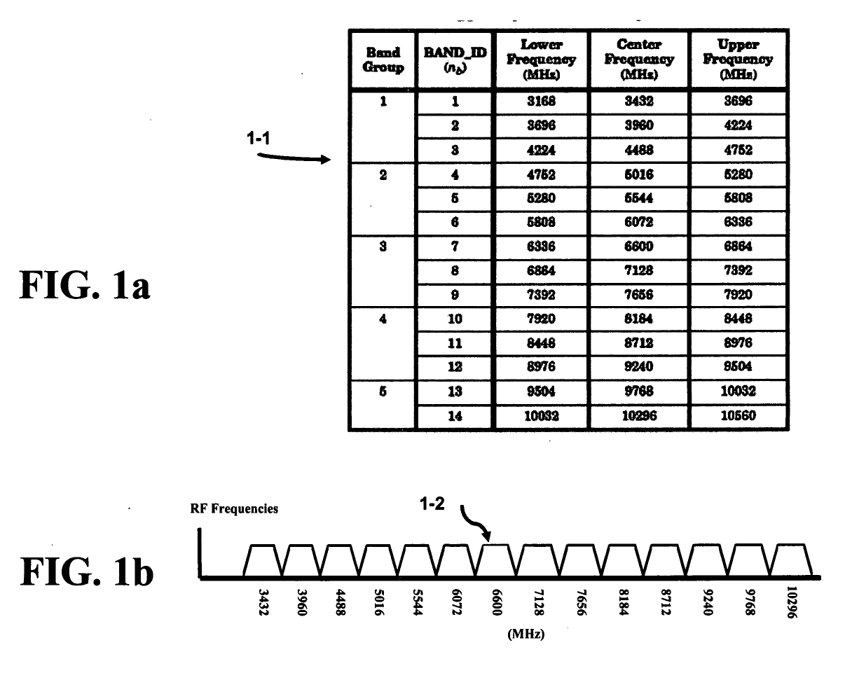

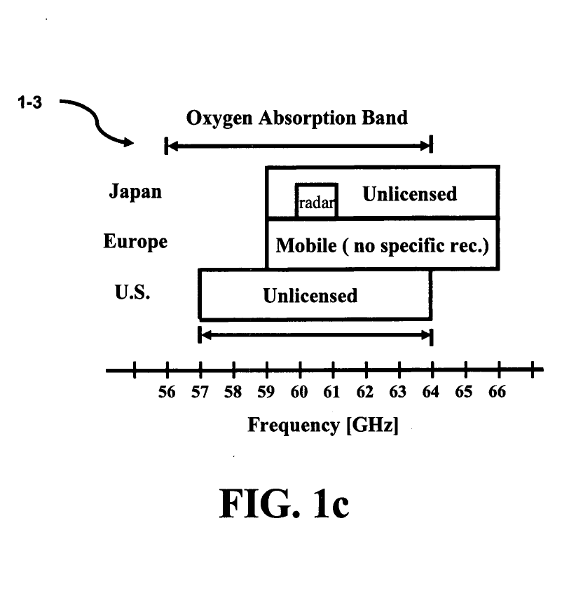

### DETAILED DESCRIPTION OF THE INVENTION

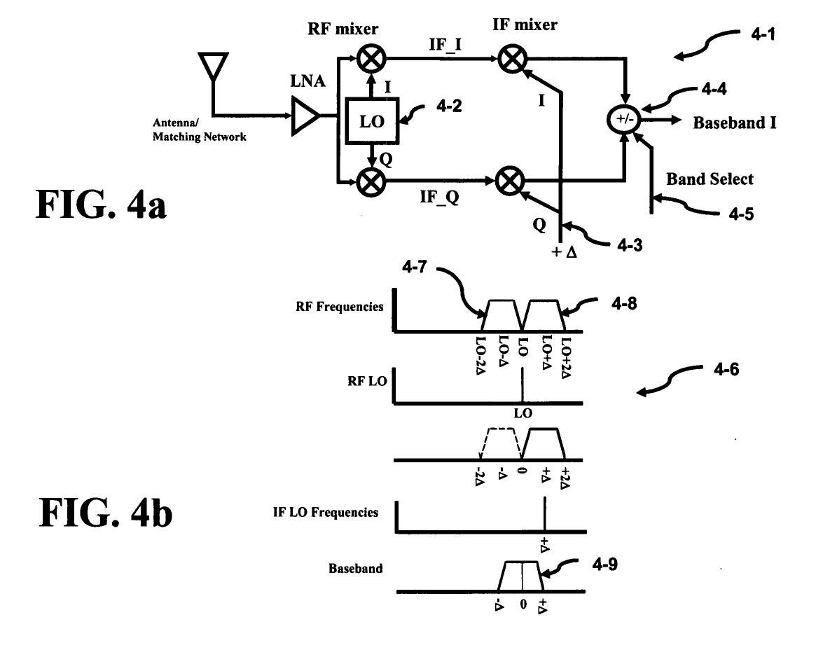

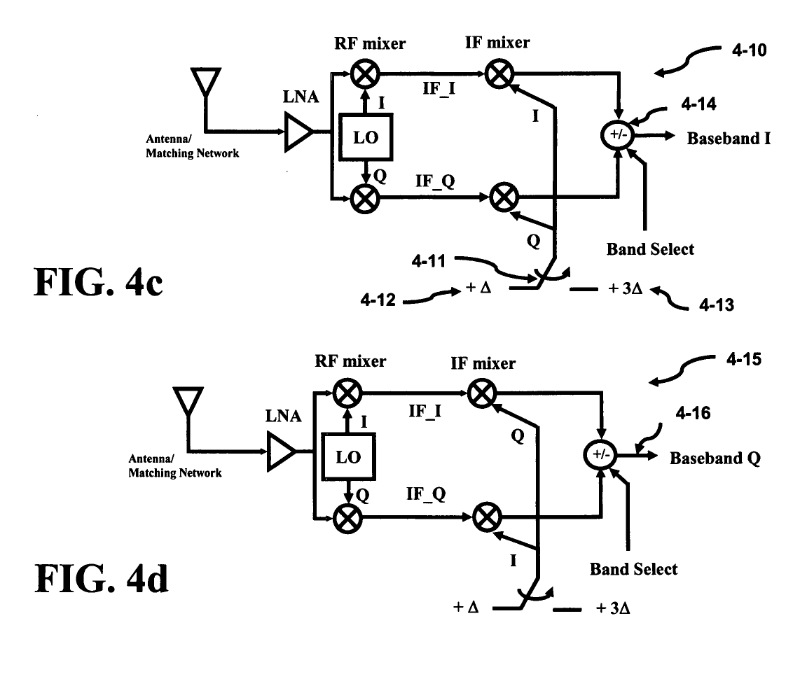

A simple conceptual diagram 4-1 of one aspect of the invention is illustrated in FIG. 4a. The antenna and LNA have been described before and will not be further discussed. A constant LO signal 4-2 is applied to the RF mixers. Assume that the RF frequency band consists of two bands 4-7 and 4-8, each 2Δ wide, as illustrated in the diagrams 4-6 of FIG. 4b. The IF LO mixers have an I and Q signal applied at a frequency of +Δ 4-3. The baseband signal 4-9 is indicated in the lowest waveform of FIG. 4b. Note by changing the band select signal 4-5 to the adder/subtractor 4-4, the other band can be extracted. When one band is extracted, the other band appears as the image and is subtracted out. This is a Weaver architecture with the following exceptions: the LO to the RF mixer remains constant and is positioned at the mid-point of the band spectrum, an IF LO oscillator with the I and Q sinusoid is applied to 4-3 with a frequency that is half the bandwidth of one of the two bands 4-7 and 4-8 and creates a zero-IF response, and finally, the band select signal 4-5 selects which one of the two bands 4-7 and 4-8 is the image and passes the other band as the extracted signal. The extracted signal is available at the output of the adder/subtractor 4-4.

A slight modification of the invention 4-10 is depicted in FIG. 4c. The RF frequency contains 4 bands each with a bandwidth of 2Δ. The LO for the RF mixer is positioned between the second and third bands. The IF mixer uses the switch 4-11 to select either the +Δ 4-12 or the +3Δ 4-13 and applies this LO to the IF mixer. The band select determines whether one of the bands in the positive or negative frequencies is selected. FIG. 4d illustrates a similar architecture 4-15 as in FIG. 4c except that the I and Q sinusoidal frequencies are flipped to the IF mixers. This results in the generation of a baseband Q signal 4-16 instead of the baseband I signal 4-14.

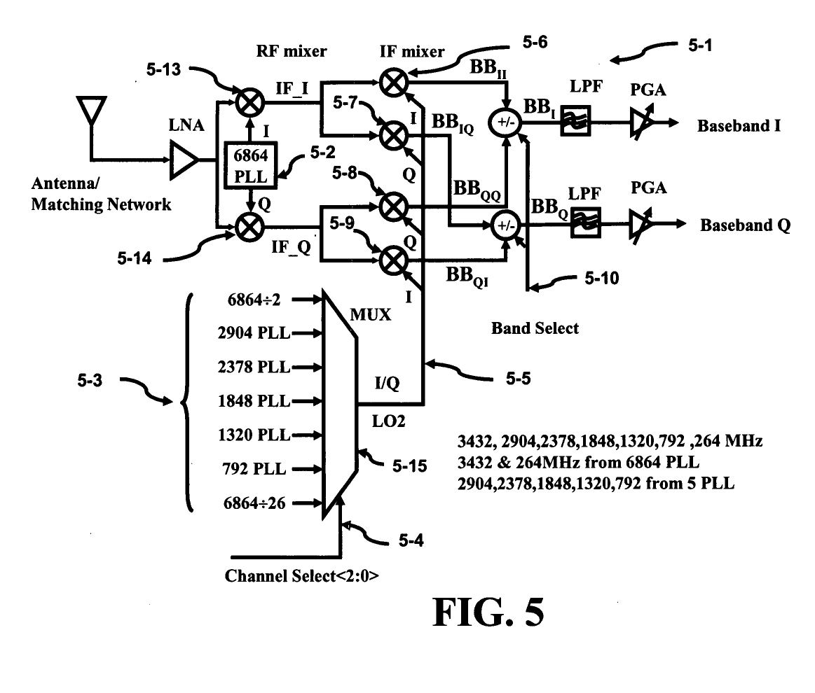

Conceptually, the two architectures and frequency plan given in FIG. 4c and FIG. 4d can be combined into one receiver architecture 5-1 as shown in FIG. 5 and enhanced. The RF mixers 5-13 and 5-14 can be shared between the two architectures 4-10 and 4-15. This is a reduction in area and potentially can result in lower power.

Theory of Operation: RX

At the antenna input, the desired RF signal along with an image exists. This is shown in equation 1. Here the ω_{carrier} equals the summation of the two local oscillators or ω_{LO1}+ω_{LO2}. In addition, ω_{signal} is equivalent to the baseband signal −ω_{baseband}.
RFᵢₙ=A_{rf} cos{(ω_{carrier}+ω_{signal})×t}+A_{image} cos{ω_{image}×t} (1)

The first quadrature RF mixers 5-13 and 5-14 in FIG. 5 translate the incoming RF signal using equation 1 into an I and Q IF signal components. Notice that the quadrature RF LO1 oscillators can distinguish the image signal which is on one side (negative side) of the LO2 from the desired signal which is on the other side (positive side) of LO2. Equation 2 and equation 3 reinforce this aspect.
IF_{I}=[A_{rf} cos{(ω_{carrier}+ω_{signal})×t}+A_{image} cos{ω_{fr}_{_{—}}_{image}×t}]cos(ω_{LO1}×t)=½[A_{rf} cos{(ω_{LO2}+ω_{signal})×t}+A_{image} cos{(ω_{LO2}−ω_{if}_{_{—}}_{image})×t}] (2)
IF_{Q}=[A_{rf} cos{(ω_{carrier}+ω_{signal})×t}+A_{image} cos{ω_{fr}_{_{—}}_{image}×t}]cos(ω_{LO1}×t)=½[A_{rf} cos{(ω_{LO2}+ω_{signal})×t}−A_{image} cos{(ω_{LO2}−ω_{if}_{_{—}}_{image})×t}] (3)

The outputs of IF signals are furthered down-converted by the I and Q LO2 signals in the baseband IQ mixers 5-6 through 5-9 to generate BB_{II}, BB_{QQ}, BB_{IQ} and BB_{QI}. Notice that image component between two corresponding equations have a sign difference (compare equation 4 and equation 5). This aspect can be used to cancel the image. In addition, by changing the polarity of the select bit, the opposite situation occurs. In this case, the image is passed while the signal is cancelled.
BB_{II}=½[A_{rf} cos{(ω_{LO2}+ω_{signal})×t}+A_{image} cos{(ω_{LO2}−ω_{if}_{_{—}}_{image})×t}]×cos(ω_{LO2}×t)=¼[A_{rf} cos(ω_{signal}×t)+A_{image} cos(ω_{image}×t)] (4)
BB_{QQ}=½[A_{rf} sin{(ω_{LO2}+ω_{signal})×t}−A_{image} sin{(ω_{LO2}−ω_{if}_{_{—}}_{image})×t}]×sin(ω_{LO2}×t)=¼[A_{rf} cos(ω_{signal}×t)−A_{image} cos(ω_{image}×t)] (5)
BB_{IQ}=½[A_{rf} cos{(ω_{LO2}+ω_{signal})×t}+A_{image} cos{(ω_{LO2}−ω_{if}_{_{—}}_{image})×t}]×sin(ω_{LO2}×t)=¼[A_{rf} sin(ω_{signal}×t)+A_{image} sin(ω_{image}×t)] (6)
BB_{QI}=½[A_{rf} sin{(ω_{LO2}+ω_{signal})×t}−A_{image} sin{(ω_{LO2}−ω_{if}_{_{—}}_{image})×t}]×cos(ω_{LO2}×t)=¼[A_{rf} sin(ω_{signal}×t)−A_{image} sin(ω_{image}×t)] (7)

The selection of the desired Channel ID is determined by the three bit signal called Channel Select. One of seven LO2 ranging from 264 MHz to 3432 MHz is selected and applied to the signal wire 5-5. Each LO2 frequency has an in phase and quadrature phase component.

The purpose of Band Select bit 5-10 is to select the signal located either on the positive side or the negative side of the 6864 MHz LO1 that was applied to the center of the UWB bandwidth. For example, to receive the signal in the channel located at 7128 MHz, the 264 MHz LO2 is selected and applied to the IF mixers. Since the LO1 frequency is set at a constant 6864 MHz value, the image signal is at 6600 MHz. Because of the Weaver architecture, the image signal is eliminated as indicated in equation 8 and equation 9 when the band select equals 1.
BB_{I}=BB_{II}+BB_{QQ}=½[A_{rf} cos(ω_{signal}×t)] (8)
BB_{Q}=BB_{IQ}+BB_{QI}=½[A_{rf} sin(ω_{signal}×t)] (9)

Similar argument can be applied to extracting the signal in located on the negative side of LO1. The band select bit is set to 0 as shown in equation 10 and equation 11 when the band select equals 0.
BB_{I}=BB_{II}−BB_{QQ}=½[A_{image} cos(ω_{image}×t)] (10)
BB_{Q}=BB_{IQ}−BB_{QI}=½[A_{image} sin(ω_{image}×t)] (11)

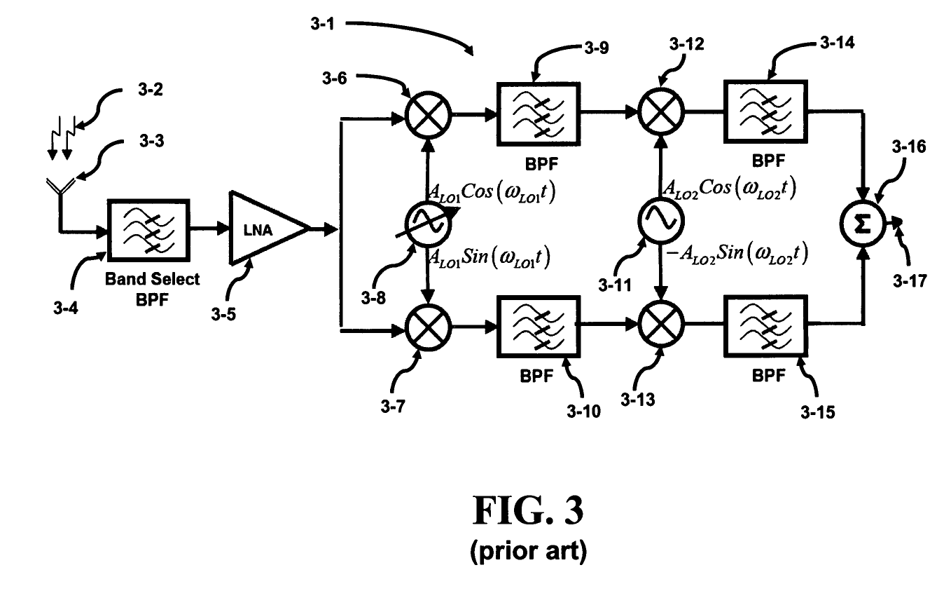

A Weaver Architecture with variable-zero-IF is provided by the lead 5-5 and is applied to the second set of mixers 5-6 to 5-9. For a comparison, the traditional Weaver Architecture shown in FIG. 3 selects the channel or band by using a variable LO 3-8 in the RF mixers 3-6 and 3-7. The second set of IF mixers 3-12 and 3-13 uses the LO 3-11 which has a fixed IF frequency. The result of this mixings generates a non-zero-IF. The image signal in the conventional Weaver Architecture is formed only on one side of the first LO.

The invention in FIG. 5 exploits the image rejection properties in the Weaver Architecture even further. In addition, we use variable IF instead of a fixed IF to perform channel selection. The secondary image in the Weaver Architecture is also avoided by the use of zero-IF in the second group of mixers for all channels. Note that the switch 4-11 illustrated earlier in FIG. 4c has been replaced by a MUX controlled by the channel select signal 54. Finally, the band select 5-10 can select the signal located in either the negative or positive frequencies surrounding the LO1 frequency.

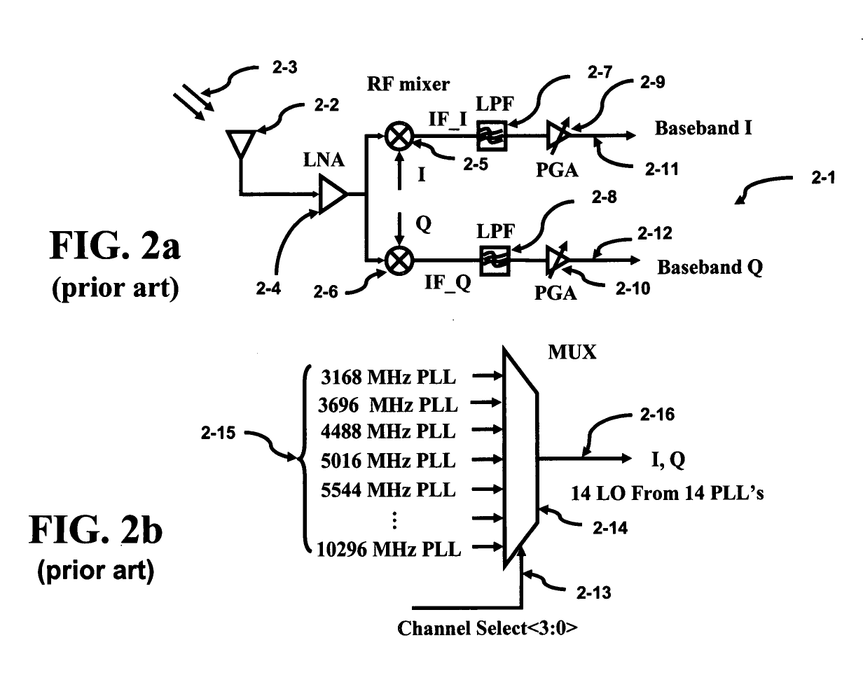

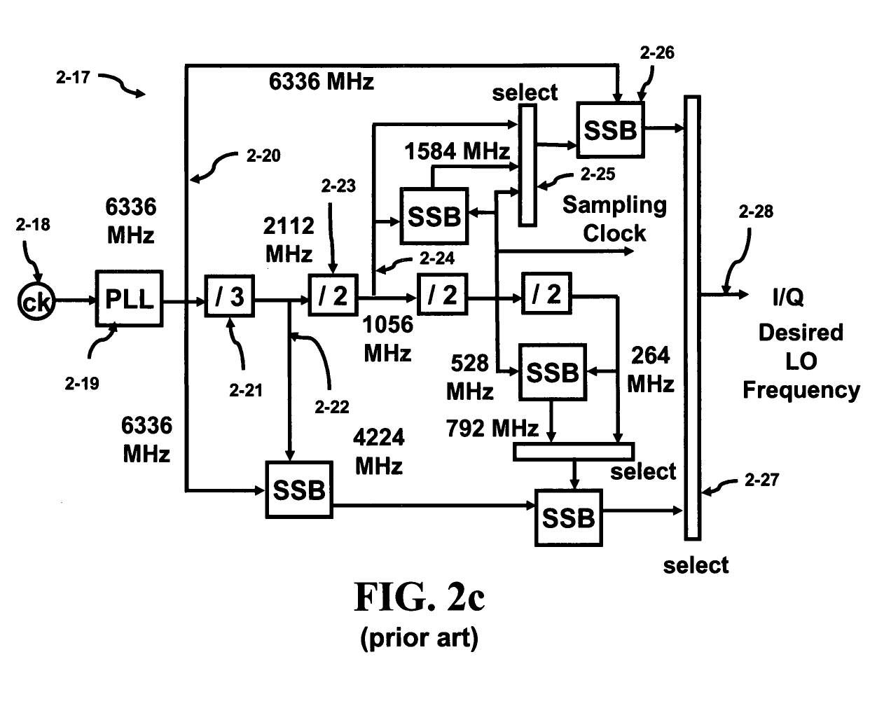

This version of the invention only requires six synthesizers 5-3 instead of the fourteen synthesizers mentioned in FIG. 2b to cover entire UWB band. The six PLL frequency plan consists of one RF PLL and five IFPLL. The RF PLL generates a quadrature LO at 6864 MHz. The five IFPLL outputs are at 792, 1320, 1848, 2376 and 2904 MHz.

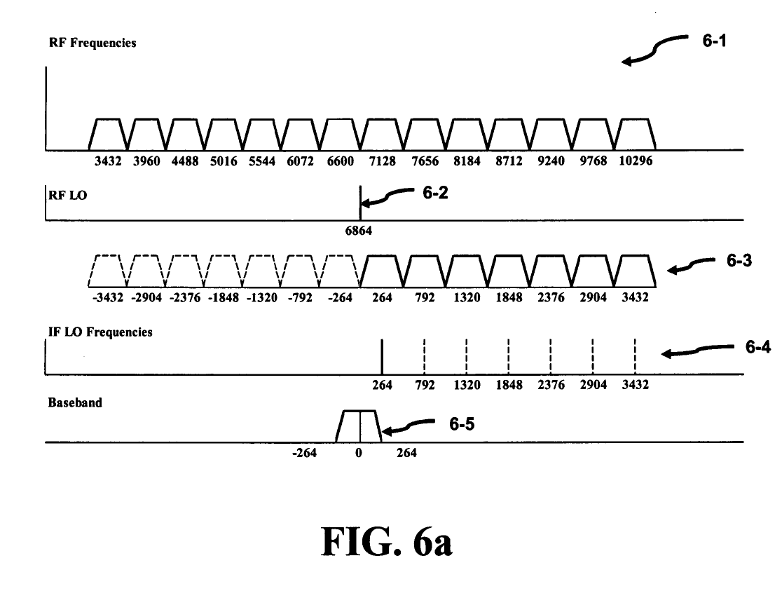

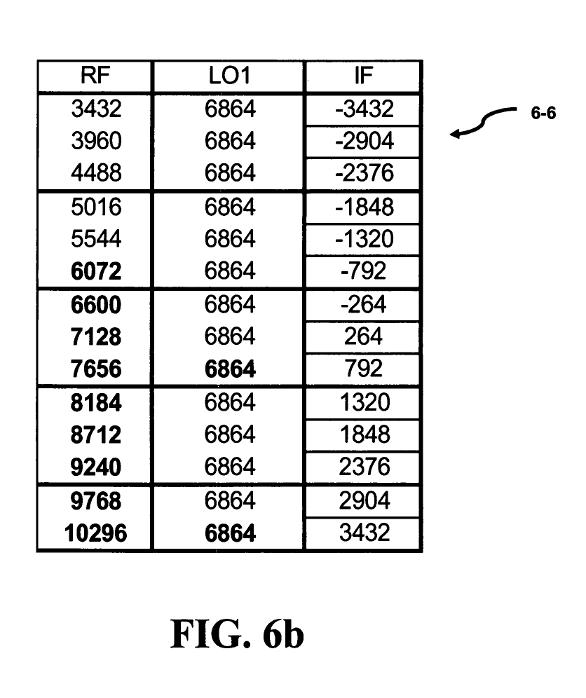

The spectrum diagrams for the receiver section 6-1 given in FIG. 6a describes the operation of the invention, but the same arguments apply to the transmit section as well. The frequency plan in the receiver section is now described. The first LO 6-2 for the RF mixers is placed between the seventh and eighth RF frequency bands as illustrated in FIG. 6a. Note that this LO generates a constant frequency, unlike the case described in FIG. 3. This LO at 6864 MHz translates the RF frequencies to IF −3432 to +3432 MHz as shown in 6-3. FIG. 6b tabulates these frequencies in the table 6-6. Next the MUX 5-15 in FIG. 5 selects which IF LO frequency 6-4 to select. This downconversion generates the baseband signal 6-5 as the output. This architecture uses the quadrature mixer in the first conversion to provide both positive and negative IF signals to the second mixer. If the positive band is selected, the signal in negative band becomes image and vice versa.

Since the IF is symmetrical about DC, only seven LO's are needed to selects 14 channels in this frequency plan. The unique selection of LO at 6864 MHz has additional advantages. The 6864 Mhz LO can be furthered divided to obtain the frequencies 264, 528 and 3234 MHz IQ signals. These signals can be used for the IF LO and as well as 528 MHz sampling clock for the baseband processor saving three synthesizers. The UWB specification calls for the sampling clocks to be used from the same clock.

One of main advantage of this architecture is that the dividers are operating at half of maximum RF frequency, thereby, saving power consumption and complexity. IQ mismatch is reduced by a factor of three since the maximum IF frequency is 3432 MHz.

Second, the LO input to the RF mixers does not need multiplexing which saves power consumption. Consider a direct conversion, for example, the LO signal would need to be multiplexed and applied to the RF mixers depending on the channel. The range of the RF LO can extend from 3 to 10 GHz. This would require a large number of RF LO's at high frequencies and consume significant amounts of power. In present invention, the multiplexing is only done only at IF mixers which occurs at a lower frequency range of 264 MHz to 3432 MHz and dissipates much less power.

Third, all the IF VCO can be implemented with ring oscillators instead of LC oscillator. The area occupied a LC oscillator is significantly larger than a ring oscillator. Thereby significant reduction dies area occupied by LO generation blocks.

Assuming IQ mismatches mainly comes from LO phases, low IF frequency has robust IQ accuracy. This translates to better receive and transmit EVM (Error Vector Magnitude).

One of the tough specifications of UWB is that center carrier leakage is in the transmit spectrum mask. It is well known that the leakage is due to DC offset of the I/Q modulator and leakage through the LO switches. The second path is frequency dependent. The choice of the lower IF alleviates this problem.

Spurious performance or image rejection is only limited by the first LO IQ accuracy at 6864 MHz, which is easier to achieve than attempting to perform the first LO I/Q at 10 GHz.

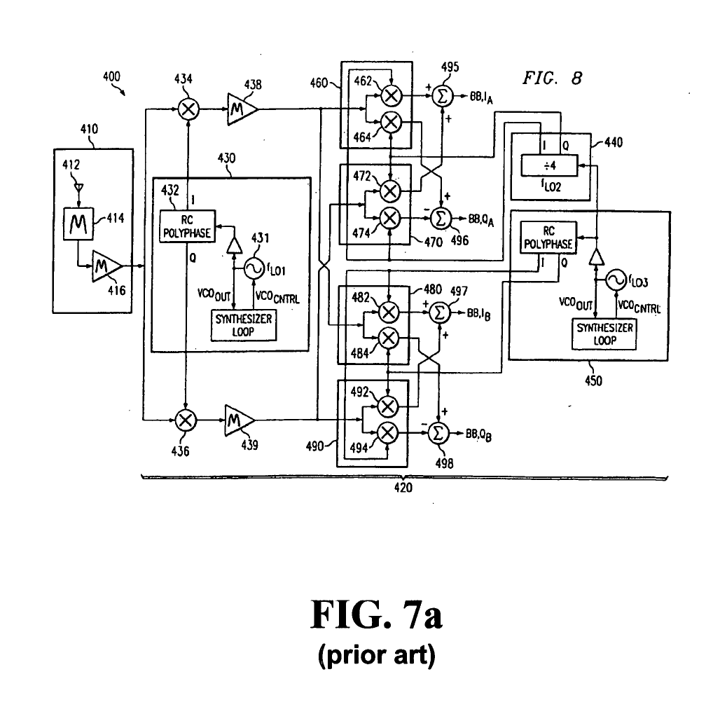

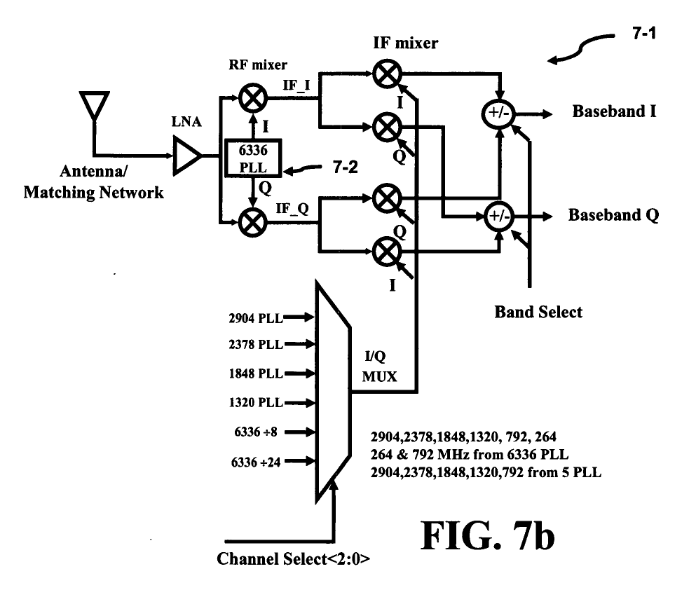

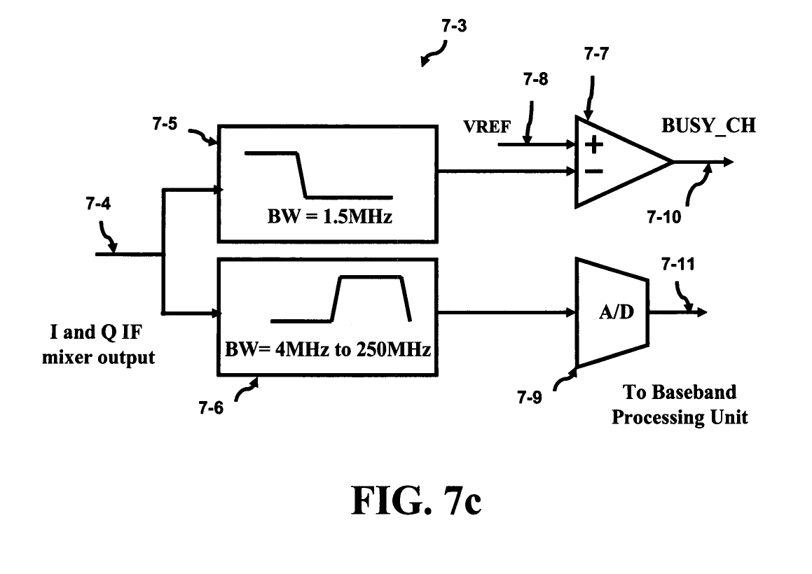

FIG. 7A illustrates a Weaver receiver architecture that is used in cellular narrow band systems. This figure has been extracted from a Hajimiri et. al. patent, U.S. Pat. No. 6,917,815, hereafter called “Hajimiri”. The invention presented in this specification overcomes several shortcomings pointed out by Hajimiri.

As indicated in Hajimiri in the second paragraph of column 9; “In the concurrent downconversion scheme, however, since the unwanted image signal is one of the two desired signal bands, there is no attenuation of the image by any of the antenna, the front-end bandpass filter or the dual-band LNA. Thus, one must rely solely on the image rejection of Weaver's single sideband downconverter, which is limited by the phase and amplitude mismatch of the quadrature local oscillators and signal paths, and can only provide about 20-40 dB attenuation of the unwanted image in each band. This is clearly insufficient image rejection for the intermediate frequency signals and thus fails as a solution to the concurrent dual-band problem.”

Our invention shows how the image rejection issue raised by Hajimiri is not a problem in the Weaver architecture proposed for the UWB system that is described in this specification. This basically occurs because while Hajimiri deals with a narrow band cellular signal, while the UWB system is a wide band signal. Unlike the UWB system, a typical GSM cellular system needs to deal with signal levels as low as −106 dBm. Due to wide bandwidth of UWB systems, the noise floor is −86 dBm without processing gain.

Thus, the issues limiting Hajimiri do not have an influence or can be significantly reduced in the UWB architecture system. A second important issue is the maximum power levels of the cellular and UWB systems. The UWB has much lower power levels. A cell phone tower can transmit as much as 30 dBm while the UWB system transmits only −41 dBm/MHz with peak power of −27 dBm.

The UWB system is designed for Personal Area Network (PAN) applications. In such a typical application, there can be several UWB transmitters within a given PAN area. Consider the case of only two transmitters. The first transmitter antenna is located 1 meter from the receiver antenna and acts as an interferer. The second UWB transmitter antenna is 15 meters away from the receiver antenna and transmits channel information which is desired to be captured, received and processed by the receiver.

The interferer signal sustains a loss while propagating in free space to the receiver's antenna. This loss can be determined by using the standard “Friis” equation, which can be used to determine the free space loss between isotropic radiators and is defined as:
Loss(in dB)=[32.44+20 log(dist in km)+20 log(freq in MHz)]dB (12)

Equation 12 is used to determine the minimum case path loss at two different frequencies (where k=7 and 1, respectively) at −k frequencies with regard to the center of the UWB bandwidth spectrum. For the case of k=−7, the frequency band of 3.4 GHz has a loss of 43 dB after propagating through a 1 meter distance. If k=−1, the frequency band of 6.6 GHz has a loss of 49 dB after propagating through a 1 meter distance.

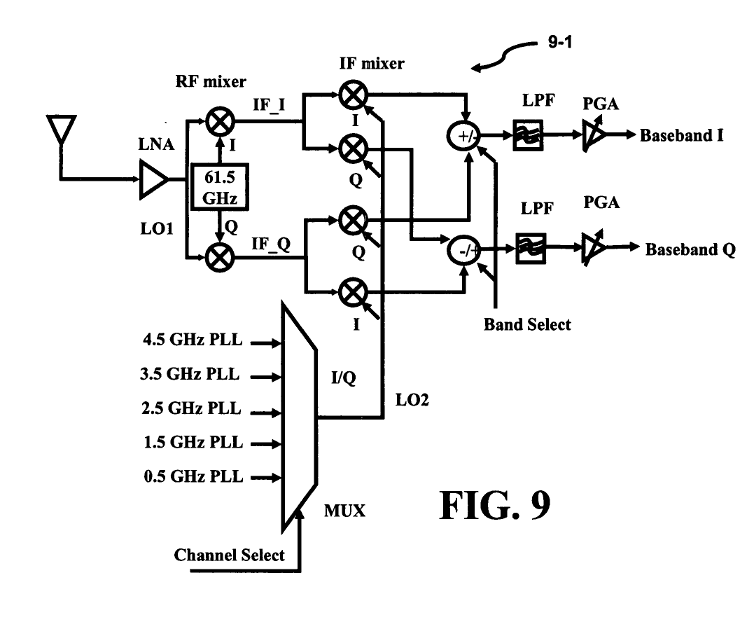

In present submicron technology, with careful layout and well characterized foundry device mismatch data, an image rejection 35-45 dB can be achieved depending on the channel frequency of our IF architecture. It can be shown that image rejection is function of frequency. Our unique architecture further relaxes the matching requirement since our maximum IF is 3432 MHz. This eliminates the need for the complicated DUAL-BAND FRONT TRANSFER FUNCTION as described in FIG. 9 of Hajimiri.

It can be shown that the UWB system architecture presented in this specification offers several features over the previous prior art. The first aspect allows robust operation over this range of image rejection values. In addition, a second aspect does not require the LO frequency of the RF to IF conversion to have an offset from the mid-point of the desired signal and the image signal.

The FCC requires that the UWB transmitters have a maximum power level of −41 dBm/MHz. The −41 dBm signal is an average power which can attain a peak power as high as −27 dBm. As long as both the signal and the image contain UWB signals, an average power of −41 dBm can be assumed in the following analysis.

Thus, in the case of the interferer UWB transmitter, the previous information of the path loss, maximum power level and the image rejection values can be used to determine the interference signal level of the image signal.

Case One: A Nearby UWB Jammer

For the case of the nearby UWB TX (located at 1 m from the receiver), the maximum power level is given as −41 dBm [average power]. Use k=−7 and −1, respectively, as before for the image signal band of 6864−k*IF. At the receiver's antenna, this signal will experience a minimum loss of 43-49 dB, respectively. Since the maximum power level is −41 dBm, the interference signal level at the antenna when k=−7 is, −41 dBm−43 dB=−84 dBm. Similarly, the interference signal level at the antenna when k=−1 is, −41 dBm−49 dB=−90 dBm.

As mentioned earlier, the image rejection can range between 35-45 dB. Thus, when k=−7, the inference signal level of the nearby UWB TX will be −84 dBm−35 dB=−119 dBm while the interference level will be −129 dBm for the case of an image rejection of 45 dB. For the case where k=−1, the inference signal level of the nearby UWB TX will be −90 dBm−35 dB=−125 dBm while the interference level will be −135 dBm for the case of an image rejection of 45 dB.

The next important parameter to determine is the thermo noise floor of a UWB signal which indicates the boundary between a potentially detectable signal and noise. Since the UWB signal bandwidth is 528 MHz, the thermo noise floor for the UWB system can be determined by using the following relationship given in equation 13:
Thermo noise floor(dBm)=−174 dBm/Hz+10*log(528*1E6)=−86.7 dBm. (13)

Thus, the maximum detectable signal level of the UWB signal is −86.7 dBm. Anything below this value is considered as noise. A UWB receiver requires 4 dB to 20 dB of SNR depending on the data rate. A typical receiver has sensitivity threshold set to −86.7 dBm+SNR. As long as the signal level is less than −82.7 dBm, the packet of information will not be detected.

The interference level determined earlier of the jamming UWB signal ranged from −119 dBm to −135 dBm. This implies that the jamming signal ranges from 33 dB to 49 dB below the thermo noise level, thus the image rejection of a nearby UWB jamming signal is not a limiting factor in the limitation of the system. Therefore, the present invention is not influenced by a nearby UWB jamming signal and the architecture is a viable solution to UWB system.

In addition, assume that the image rejection is increased to 20 dB, the upper range mentioned by Hajimiri. The jamming signal ranges from 18 dB to 34 dB below the thermo noise level. In some cases, although it is an extreme example, the UWB system may still operate. Next, a second case will be considered for a WLAN interferer.

Case 2: A WLAN Interference Signal

In PAN applications, besides a UWB interfering signal, WLAN devices (e.g., 802.11) can create an undesired interference signals. The WLAN output power levels can be as high as 20 dBm within a bandwidth of 20 MHz. This high power level will cause the UWB receiver system to fail if the WLAN transmitter is 1 m away and the WLAN signal falls right on top of either image or signal channel. The WLAN signal desensitizes the LNA and mixer stages, which can become fully saturated. Therefore, the UWB receiver needs to be cleaver enough to avoid the WLAN interference signal or increase the linearity of the LNA and mixer. Usually, the linearity can not be achieved without a compromising effect such as designing a more power dissipative circuit or using more silicon area. Both of these design issue constraints can be costly. Another approach to avoid a WLAN interference signal is preferred.

A Wireless LAN Avoidance Scheme

One possibility is to use a Receiver Signal Strength Indicator (RSSI) signal having at least one detector connected to the each of the I and Q IF mixer outputs. An example of an RSSI circuit 7-3 is illustrated in FIG. 7c. The output of the IF mixer is connected to the lead 7-4. The first RSSI circuit 7-5 is a low pass filter and has a 1.5 MHz BW. This filter is used to determine if the WLAN signals are present. At the beginning of each WLAN signal, there is a 1.5 MHz short pre-ample pilot signal which has constant amplitude. Under the presence of a strong WLAN interference signal, this RSSI output signal will be larger than some predetermined reference signal VREF 7-8. The comparator 7-7 is used to enable the signal BUSY_CH 7-10. The BUSY_CH can be used to switch the transceiver to a different frequency band ID. Since there are two RSSI circuits; one for the I and one for the Q IF mixer outputs, the two BUSY_CH's signals can be connected to an OR gate to detect if either the I or Q IF signal senses the WLAN signal.

If a WLAN RSSI reading indicates the generation of a BUSY_CH signal then the baseband processor can instruct the UWB receiver system to hop to a different frequency band to avoid the WLAN interference signal. This event may cause the loss of a package of information but will allow the remaining packets to be received. If a packet was lost, then a request can made to resend this packet. The current UWB specification does not specify such requirement and may be a useful technique to integrate into the UWB system specification.

When a WLAN signal is not detected, the UWB signal has a 4.25 MHz sub-carrier spacing, therefore, the Band Pass (4-250 MHz BW) filter 7-6 passes the received signal to the A/D 7-9. The output of the A/D 7-11 is then sent to the baseband processing unit to extract the signal.

Hajimiri also indicates the following in the fourth paragraph of column 9. “By offsetting the first local oscillator frequency LO1 from the midpoint between bands A and B, as shown in the figure, applying the Weaver image rejection technique now not only does not suffer from the aforementioned drawbacks, but actually significantly improves the image rejection. The key to this solution is to offset the LO1 frequency of the first stage of the image-rejection architecture from the midpoint of the two bands of interest in such a way that the image, fIA, of the first band, fA, falls at the middle attentuation region of the front-end subsystem transfer function. Similarly, the image of the second, upper desired band, fB, falls at outside the pass-band of the front-end at fIB and will also be attenuated.”

The invention given in this specification for the UWB system has demonstrated that the image signal is not necessarily a critical concern. Because of this issue, the UWB architecture does not need to offset the Local Oscillator (LO) as Hajimiri is required to do. Furthermore, although the range of 35 to 45 dB image rejection has been shown to be achievable, a possibility exists for certain situations for the UWB system to operate with much less image rejection.

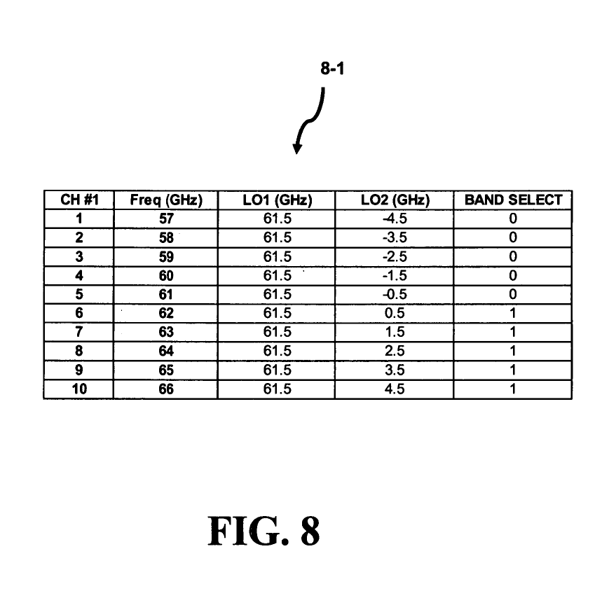

The numbers for the frequency plan using the Weaver architecture for the 60 GHz UWB system is provided the table 8-1 in FIG. 8. The CH number is given in the first column, while the center frequency is shown next. The next two columns indicate the LO1 and LO2 frequencies. Finally, the last column provides the band select bit value. Each channel has a bandwidth of 1 GHz.

The same concepts can be applied to cover the architecture 7-1 in FIG. 7b where only 12 bands are used. In this case, only five synthesizers are needed. RF LO 7-2 can be at 6336 MHz and two IF 264 MHz, 792 MHz IQ signals can be derived from 6336 MHz LO. Otherwise, this architecture operates very similar to the one given in FIG. 5.

The architecture and frequency plan for the 60 GHz receiver is illustrated in FIG. 9. Both receivers shown in FIG. 7b and FIG. 9 have a similar architecture. The primary difference is that the RF frequency range of FIG. 9 extents to 60 GHz. Thus, the architecture given in FIG. 9 needs no further description.

Theory of Operation: TX

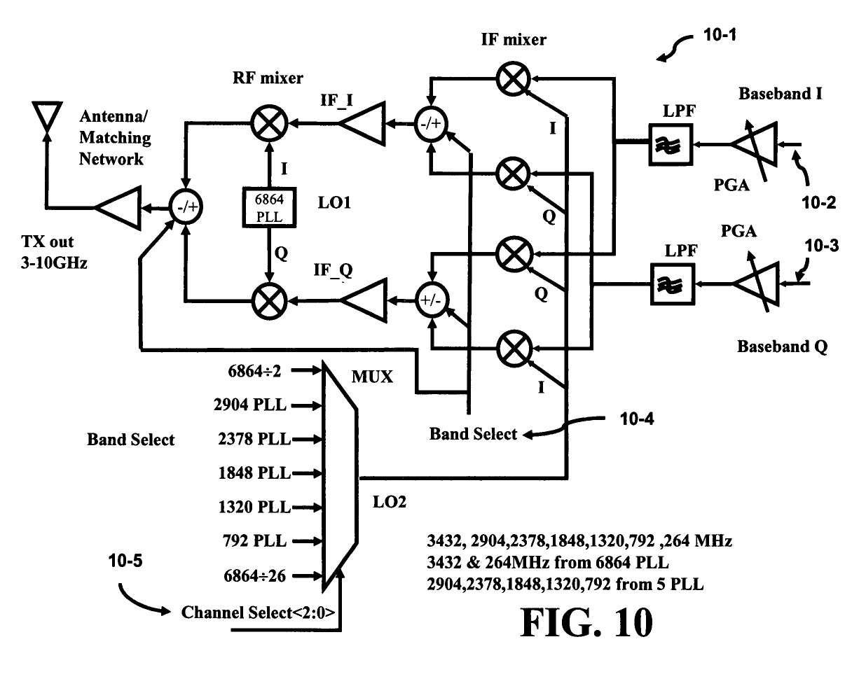

The architecture and frequency plan for the MBOA transmitter section 10-1 is shown in FIG. 10. The baseband I and Q signals (10-2 and 10-3) are applied to the PGA which is then Low Pass Filtered (LPF). The first four quadrature IF mixers translate the incoming baseband signals to an IF frequency. Depending on the channel select value 10-5, the IF LO can be selected from 264 MHz to 3432 MHz. The output IF signals are in phase and quadrature form, and are up-converted by the 6864 IQ LO signal in the RF mixer. Since each RF mixer generates the desired and image signal, the I/Q signals can be used to cancel the image. For example, at the output of RF mixer, the signal can be at 6864+/−k*IF, where k is the selected channel. Similar to the receiver, if the positive band is selected, the signal in negative band becomes image and vice versa. A single band select signal selects k*IF and determines if the signal resides in the positive or negative range. For example, if we want to transmit the signal at +3432 then the IF needs to be 3432 MHz and the band select bit has to be negative. In addition, if the band select bit selects the positive polarity then, the transmitter output is 6864+IF.

The frequency translation of the baseband signal ω_{signal} in the transmitter section is described. The first four quadrature mixers translate the incoming baseband signal to IF frequency using an LO2 IF carrier selected by the three bit channel select control 10-5. The output of the up converted IF signals are in phase and quadrature form and are summed together using the band select signal 10-4. The IF signal is further upconverted to RF frequencies by the LO1. If band_select=1, the higher band is selected as indicated in equation 14 and equation 15. The purpose of band select bit is to distinguish whether the transmitter output is selected from the positive or negative side of the constant 6864 MHz LO1 clock frequency. For example, if the transmitter generates a channel at 7128 MHz, a 264 MHz IF is selected. At the IF output, the incoming baseband signal needs to be on the POSITIVE side of LO2 signal. This operation is accomplished as indicated in equation 14 and equation 15.
IF_{—}I=cos(ω_{LO2}×t)×cos(ω_{signal}×t)−sin(ω_{LO2}×t)×sin(ω_{signal}×t)=cos{(ω_{LO2}+ω_{signal})×t} (14)
IF_{—}Q=sin(ω_{LO2}×t)×cos(ω_{signal}×t)+cos(ω_{LO2}×t)×sin(ω_{signal}×t)=sin{(ω_{LO2}+ω_{signal})×t} (15)

Since each mixer generates LO+IF and LO−IF or signal and image, the image portion of this signal can be subtracted out. These two signals IF_I and IF_Q are then up-converted by a 6864 MHz IQ LO1 oscillator signal in the RF mixer. The signal at the antenna is given in equation 16.
RF_OUT=cos(ω_{LO1}×t)×cos{(ω_{LO2}+ω_{signal})×t}−sin(ω_{LO1}×t)×sin{(ω_{LO2}+ω_{signal})×t}=cos{(ω_{LO1}+ω_{LO2}+ω_{signal})×t} (16)

If Band_select=0 the lower band is selected as indicated in equation 17 and equation 18. Similarly, if we want to generate 6600 MHz at channel, we will choose an IF of 264 MHz. At the output of the IF mixers, the incoming baseband signal is selected to be on the negative side of LO2 signal. This operation is accomplished using equation 17 and equation 18. The IF signal is further up converted to RF frequency by LO1. Since each mixer generates LO−IF and LO+IF or signal and image, the image potion is subtracted. This process is done by use of quadrature LO1 signal in as indicated in equation 19.
IF_{—}I=cos(ω_{LO2}×t)×cos(ω_{signal}×t)+sin(ω_{LO2}×t)×sin(ω_{signal}×t)=cos{(ω_{LO2}−ω_{signal})×t} (17)
IF_{—}Q=sin(ω_{LO2}×t)×cos(ω_{signal}×t)−sin(ω_{LO2}×t)×sin(ω_{signal}×t)=sin{(ω_{LO2}−ω_{signal})×t} (18)
RF OUT=cos(ω_{LO1}×t)×cos{(ω_{LO2}+ω_{signal})×t}+sin(ω_{LO1}×t)×sin{(ω_{LO2}−ω_{signal})×t}=cos{(ω_{LO1}−ω_{LO2}+ω_{signal})×t} (19)

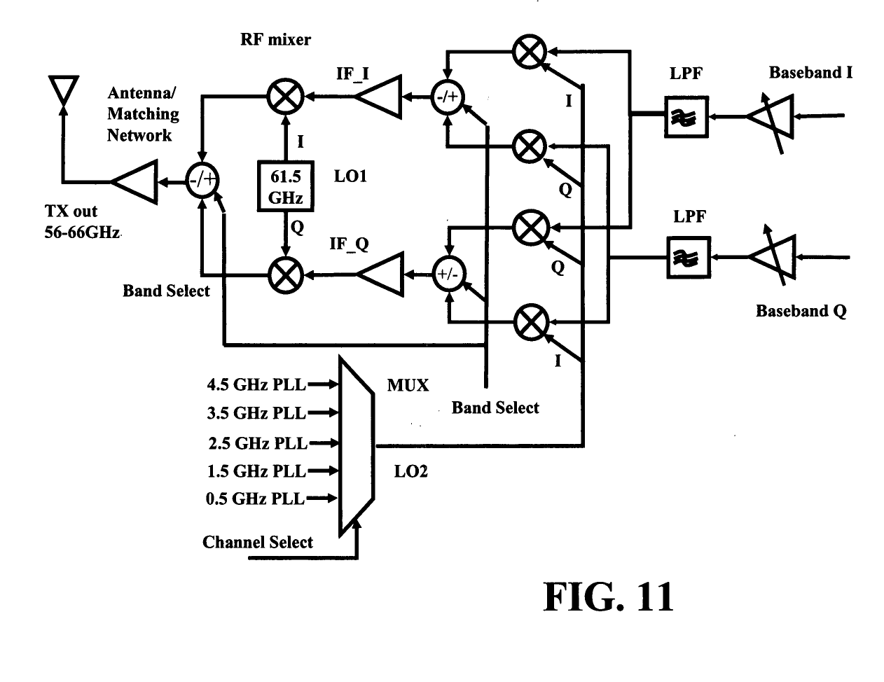

The architecture and frequency plan for the 60 GHz transmitter section 11-1 is shown in FIG. 11. Note that the architecture is very similar to the architecture given in FIG. 10. Thus the detailed description is not required. Again, the primary difference is that the frequencies in FIG. 11 have been increased to the 60 GHz range.

Finally, it is understood that the above descriptions are only illustrative of the principles of the current invention. In accordance with these principles, those skilled in the art may devise numerous modifications without departing from the spirit and scope of the invention. For example, the UWB specification calls for the sampling clocks to be used from the same clock but this general technique can be used with sampling clocks from other sources. The reference clocks can be obtained from external sources off chip, LC tank circuits or PLL's. The actual choice of the clock source will depend on a number of issues, including, area availability, and ease of use. The technology to form the circuits can be formed using the MOS or BJT technologies, for example. In addition, the RSSI circuit can be incorporated into all of the receivers previously described. Also, the matching network associated with the antenna may be eliminated in certain cases. Finally, the BPF, LPF and amplifiers (although they may not be shown specifically) can be incorporated into the design by those skilled in the art.

1. A method of achieving a frequency planning technique in a receiver system comprising the steps of;
partitioning an input frequency spectrum into an even number (n) of channels; wherein the even number (n) is greater than two;
positioning a midpoint frequency in the middle of the input frequency spectrum;
utilizing the receiver system comprising;
at least one I component; and
at least one Q component;
means for using a Weaver architecture to downconvert the input frequency spectrum using an RF LO frequency equal to the midpoint frequency to generate an IF spectrum with a zero IF frequency; whereby the IF spectrum has an even symmetry based around the zero IF frequency;
assigning to the middle of each positive channel spectrum component of the IF spectrum a positive center IF LO frequency;
means for using the Weaver architecture to downconvert the IF spectrum by selecting one of the positive center IF LO frequencies to generate a set of baseband signal components;
using a band select signal to combine the set of baseband signal components; and
extracting the baseband signal from one of the channels; wherein
only the positive center IF LO frequencies are used; thereby
reducing the required number of IF LO frequencies; and
achieving the frequency planning technique in the receiver system.

2. The method of claim 1, wherein
the selection means of one of the positive center IF LO frequencies is a multiplexer controlled by a channel select signal.

3. The method of claim 1, further comprising the steps of
determining if any two of the positive center IF LO frequencies are related by a factor of two;
dividing the higher of the two IF LO frequencies by this factor of two to generate the lower IF LO frequency; thereby
removing the need to independently create the lower IF LO frequency; and further
improving the frequency planning technique in the receiver system.

4. The method of claim 1, further comprising the steps of
determining if any of the positive center IF LO frequencies are related to the RF LO frequency by a factor of two;
dividing the RF LO frequency by this factor of two to generate the positive center IF LO frequency; thereby
removing the need to independently create the positive center IF LO frequency; and further
improving the frequency planning technique in the receiver system.

5. The method of claim 1, further comprising the steps of
generating the LO frequencies using a synthesizer; wherein
the synthesizer is an oscillator selected from the group consisting of a PLL, ring oscillator, LC tank circuit, and VCO.

6. The method of claim 1, further comprising the steps of
applying a sampling clock to a state machine to extract the baseband signal; wherein
the sampling clock is derived from one of the LO frequencies.

7. The method of claim 1, wherein
the even symmetry based around the zero IF frequency causes the positive channel spectrum component of the IF spectrum and the corresponding negative channel spectrum component of the IF spectrum to have equal bandwidths.

8. The method of claim 1, further comprising the steps of
setting all of the channels to have the same bandwidth.

9. The method of claim 1, wherein a total bandwidth of each of the channels comprises;
a first, second and third bandwidth portions; wherein
the first bandwidth portion carries a first null content;
the second bandwidth portion adjacent to the first portion carries a channel information content; and
the third bandwidth portion adjacent to the second portion carries a second null content.

10. The method of claim 9, wherein
the midpoint frequency is positioned between the third bandwidth portion of the (n/2)^{th} channel spectrum component and the first bandwidth portion of the (n/2)+1^{th} channel spectrum component.

11. The method of claim 9, wherein
the first and third bandwidth portions are equal.

12. The method of claim 11, wherein
the first bandwidth portion is less than 10% of the second bandwidth portion.

13. A method of reducing the number of required IF LO (Local Oscillators) in a transmitter system comprising the steps of;
determining a midpoint frequency of an entire frequency spectrum of the transmitter system;
partitioning the entire frequency spectrum into an even number of channels;
insuring that each channel has a corresponding symmetrical channel positioned around the midpoint frequency;
selecting a center frequency of each of the channels on either side of the midpoint frequency;
determining a frequency difference between the midpoint frequency and each of these center frequencies;
creating a set of IF LO frequencies based on these frequency differences;
creating an information content at baseband;
utilizing a Weaver architecture comprising;
at least one I component;
at least one Q component;
means for selecting one of the IF LO frequencies via a channel select digital signal;
means for mixing the IF LO frequency and the information content in a first upconversion;
means for mixing the midpoint frequency and a set of results from the first upconversion in a second upconversion; and
means for selecting either the channel or the corresponding symmetrical channel positioned around the midpoint frequency via a band select bit; thereby
reducing the number of required IF LO (Local Oscillators) in a transmitter system.

14. The method of claim 13, further comprising the steps of
determining if any two of the IF LO frequencies are related by a factor of two;
dividing the higher value of the two IF LO frequencies by this factor of two to generate the lower IF LO frequency; thereby
removing the need to independently create the lower IF LO frequency; and further
improving a frequency planning technique in the transmitter system.

15. The method of claim 13, further comprising the steps of
determining if any of the IF LO frequencies are related to the midpoint frequency by a factor of two;
dividing the midpoint frequency by this factor of two to generate the IF LO frequency; thereby
removing the need to independently create the IF LO frequency; and further
improving the frequency planning technique in the transmitter system.

16. The method of claim 13, further comprising the steps of
generating the LO frequencies using a synthesizer; wherein
the synthesizer is an oscillator selected from the group consisting of a PLL, ring oscillator, LC tank circuit, and VCO.

17. The method of claim 13, further comprising the steps of
applying a sampling clock to a state machine to prepare the information content; wherein
the sampling clock is derived from one of the LO frequencies.

18. The method of claim 13, wherein
the channel and the corresponding symmetrical channel positioned around the midpoint frequency have equal bandwidths.

19. The method of claim 13, further comprising the steps of
setting all of the channels to have the same bandwidth.

20. The method of claim 13, wherein a total bandwidth of each of the channels comprises;
a first, second and third bandwidth portions; wherein
the first bandwidth portion carries a first null content;
the second bandwidth portion adjacent to the first portion carries the channel information content; and
the third bandwidth portion adjacent to the second portion carries a second null content.

21. The method of claim 20, wherein
the midpoint frequency is positioned between the third bandwidth portion of the (n/2)^{th} channel and the first bandwidth portion of the (n/2)+1^{th} channel.

22. The method of claim 20, wherein
the first and third bandwidth portions are equal.

23. The method of claim 22, wherein
the first bandwidth portion is less than 10% of the second bandwidth portion.

24. A method of achieving a frequency planning technique in a receiver system comprising the steps of;
means for partitioning an input frequency spectrum into an even number (n) of channels; wherein the even number (n) is greater than two;
means for positioning a midpoint frequency in the middle of the input frequency spectrum forming a lower side segment or and a higher side segment;
means for using a Weaver architecture to double downconvert one of the channels to a first set of results; and
means for determining whether the first set of results are added or subtracted according to a band select signal to extract a channel from the lower side segment or a channel from the higher side segment; thereby
achieving the frequency planning technique means in a receiver system.

25. A method of achieving a frequency planning technique in a receiver system comprising the steps of;
partitioning an input frequency spectrum into an even number (n) of channels; wherein the even number (n) is greater than two;
positioning a midpoint frequency in the middle of the input frequency spectrum;
positioning each channel on a lower side of the midpoint frequency equidistant from a channel on a higher side of the midpoint frequency;
performing a first Weaver downconversion operation on the input frequency spectrum using the midpoint frequency as an RF LO to obtain a IF result where the midpoint frequency has been converted to a zero IF frequency;
assigning to the middle of each positive channel spectrum component of the IF result an IF LO frequency;
applying the IF result and one of these IF LO frequencies as an IF LO to a second Weaver quadrature downconversion operation to obtain a baseband result;
selecting whether the baseband results are added or subtracted;
extracting an information content from one of the (n) channels; wherein
only the positive IF LO frequencies are used; and
reducing the required number of IF LO frequencies; thereby
achieving the frequency planning technique in the receiver system.

26. A method of achieving a frequency planning technique in a transmitter system comprising the steps of;
means for partitioning an input frequency spectrum into an even number (n) of channels;
means for positioning a midpoint frequency in the middle of the input frequency spectrun forming a lower side segment or and a higher side segment;
means for using a Weaver architecture to double upconvert a baseband signal to a first set of results; and
means for determining whether the first set of results are added or subtracted according to a band select signal to insert the baseband signal into a channel in the lower side segment or into channel in the higher side segment; thereby
achieving the frequency planning technique means in a transmitter system.
